(19) United States
(12) Patent Application Publication
(10) Pub. No.: US 2016/0282532 A1
(43) Pub. Date: Sep. 29, 2016

(54) OPHTHALMIC OPTICAL FILTERS FOR PREVENTION AND REDUCTION OF PHOTOPHOBIC EFFECTS AND RESPONSES

(71) Applicant: TECPORT OPTICS, INC., Orlando, FL (US)

(72) Inventors: Tam-Van Thanh Le, Orlando, FL (US); Joseph Moksik Kim, Saint Cloud, FL (US); Jun Chul Cha, Oviedo, FL (US)

(21) Appl. No.: 15/032,943

(22) PCT Filed: Oct. 29, 2014
(86) PCT No.: PCT/US14/62825

§ 371 Date: Apr. 28, 2016

Related U.S. Application Data
(60) Provisional application No. 61/897,398, filed on Oct. 30, 2013.

(51) Int. Cl. G02B 5/28; G02C 7/10; C23C 14/50; C23C 14/22; C23C 14/54; G02B 1/111; C23C 14/30

(52) U.S. Cl. CPC G02B 5/287; G02B 1/111; G02C 7/107; C23C 14/30; C23C 14/228; C23C 14/54; C23C 14/505; C23C 14/542

(57) ABSTRACT

A high energy, low temperature cold plasma thin film deposition process, apparatus and products are disclosed. Multi-layer thin film coatings are deposited onto polymeric substrates for ophthalmic and therapeutic applications.

### TECHNICAL FIELD

The present invention relates to a process and apparatus in the field of thin film technology for producing optical filters on polymeric substrates.

### BACKGROUND ART

A variety of technologies are available for coating substrates such as glass or polymer with multi-layered thin films to create optical filters for a variety of applications including ophthalmic lenses. Conventional coating procedures involve melt-evaporating materials to deposit layers onto a substrate by a free flow process. Free flow conventional coating procedures can be problematic, however, since they cannot produce a densely-packed surface, and as a result gaps or spaces remain in the layers that can lead to moisture and/or gas absorption.

Plasma assisted deposition procedures such as physical vapor deposition (PVD), chemical vapor deposition (CVD), plasma-enhanced chemical vapor deposition (PECVD), and other hybrid methods are known. Ion and plasma-assisted processes have improved thin film technologies by enabling better control of fabrication parameters and increased film packing density.

Optical coatings fabricated using thin film technologies are widely used for a variety of applications including ophthalmic lenses and eyewear for vision correcting and therapeutic purposes. For ophthalmic applications, polymeric substrates are generally preferred including for example, polycarbonate, allyl diglycol carbonate (e.g. CR-39®), acrylic, urethane based pre-polymer (e.g. TRIVEX®), poly(methyl methacrylate) (PMMA), polyimide film (e.g. KAPTON®), photochromic lenses, and cyclo olefin polymer (COP) (e.g. ZEONEX®). Polymeric substrates in combination with coating technologies provide a variety of benefits including scratch resistance, UV protection, temperature stability, and controlled permeation.

While thin-layered optical film filters having multiple layers can be produced on substrates such as glass, currently there is no reliable way to produce optical filters on a polymeric substrate having more than about 5 to 7 layers. In large part, this is because current processes, such as plasma deposition methods, generate high temperatures which exceed the melting temperature of polymeric materials, leading to compromises in the integrity of the substrate.

Optical filters can be applied to ameliorate certain photophobic conditions. Recently, it has been shown that light sensitivity, or photophobia, underlies a number of conditions that can be painful and debilitating (see e.g. WIPO Pub. No. WO 2012/177296 for “Apparatus And Methods For Reducing Frequency Or Severity Of Photophobic Responses Or Modulating Circadian Cycles”). The retina of the eye contains a number of photoreceptor cells including rods, cones, and melanopsin ganglion cells. Melanopsin ganglion cells are photosensitive and transmit pain signals to the brain during episodes of photophobic responses. Migraine headaches, blepharospasm, and other light-stimulated neurological reactions, including head/brain trauma, and drug-related eye problems, are exacerbated by specific, narrow wavelength bands of blue and red light, specifically at 480 nm and 620 nm wavelengths. Narrowly-defined wavelength bands within the visible spectrum are also implicated in modulating circadian rhythms.

Photophobic conditions can be treated in different ways including by selectively attenuating or eliminating the offending portions of the light spectrum that stimulate melanopsin ganglion cells. For this purpose, interference filters, also known as dichroic or dielectric filters, are of particular interest since they reflect unwanted wavelengths by incorporating high and low refractive index optical materials such as metal oxides.

While optical filters can be applied to a variety of substrates, there remains a need for an apparatus and process for producing optical filters having multiple layers in excess of 5 to 7 on polymeric substrates for a variety of uses including ophthalmic and therapeutic applications.

### DISCLOSURE OF THE INVENTION

This summary is provided merely to introduce certain concepts and not to identify any key or essential features of the claimed subject matter. The present invention relates to the manufacture of optical filters, protective or corrective ophthalmic devices, apparatus and process for the manufacture and production of such filters and devices, and to methods of treating photophobia or other light-related condition. The function of the optical filters is to modify the spectral content of light, for example, to attenuate or eliminate those wavelengths or bands of wavelengths of visual light that are associated with photophobic reactions. Narrow spectral bandwidth filters can be applied to eyeglasses and other optical surfaces to reduce the severity of photophobic and other vision-related neurological reactions.

Optical filters of the present invention reduce or eliminate specific wavelengths, reduce background ambient light that would otherwise impair clear vision, and transmit the remainder of the visual spectrum to maintain high color discrimination fidelity with low total light loss. Specific bands of wavelengths centered near 480 nm and 620 nm that are responsible for photophobic and other light-stimulated neurological responses are attenuated by products, process, and apparatus of the present invention. Other examples of light-sensitive reactions that can benefit from the present invention include head/brain trauma, and drug reaction related eye problems.

The process and apparatus of the invention for producing filters are based on the application of a deposition process that is capable of manufacturing multi-layer optical filters on temperature-sensitive substrates such as those having polymeric compositions. A modified plasma ion deposition apparatus of the invention includes a vacuum system that contains deposition sources, evaporation sources, a specialized plasma-ion assist source, and monitoring devices that are designed to deposit protective coatings for the specific ophthalmic applications mentioned above while maintaining a low substrate temperature.

The invention further provides a cold plasma process for applying spectrally selective filtering coatings to the surfaces of polymeric substrates including eyewear and light sources. The present invention can be applied to any visual or non-visual application where modification of the light spectrum is desired including, but not limited to, rejection of ultraviolet and near-infrared wavelengths.

Certain variations of the invention provide an improved high energy, cold plasma vacuum deposition apparatus and process for manufacturing optical filters based on a plasma ion assisted deposition process (PIAD) to provide metal oxide film layers on thermosensitive substrates such as polymers.

Additional aspects of the invention relate to treating photosensitive conditions with optical filters applied to polymeric substrates.

These and other variations of the present invention will be apparent from the following description, accompanying drawings, and the appended claims.

### BRIEF DESCRIPTION OF THE DRAWINGS

FIG. 1 provides a schematic representation of a thin-film deposition system according to one aspect of the invention.

FIG. 2 provides a schematic representation of a multi-layer thin-film design used to reflect specific bands of wavelengths that stimulate photophobic reactions.

FIG. 3 shows the transmittance spectrum of a protective optical filter design of the invention deposited on tinted and non-tinted eyeglass lenses.

FIG. 4 shows the transmittance and reflectance of a variation of a protective optical filter design that reduces specific reflection and includes an absorbing layer.

FIG. 5 shows the spectral transmittance of a protective optical filter design that reduces a band of red light centered near 620 nm.

### BEST MODES FOR CARRYING OUT THE INVENTION

As used herein, the term “photophobic” or “photophobic condition” refers to light sensitivity or an adverse response to light that is associated with certain neurological conditions including migraine headaches and benign blepharospasm. See, for example, M. K. Blackburn, et. al., “FL-41 Tint Improves Blink Frequency, Light Sensitivity, and Functional Limitations in Patients with Benign Essential Blepharospasm”, Ophthalmology. 2009 May; 116(5): 997-1001; PCT/US12/21500, “Methods, Systems, and Apparatus for Reducing the frequency and/or Severity of Photophobic Responses or for Modulating Circadian Cycles”; Jie Huang et al., “fMRI evidence that precision ophthalmic tints reduce cortical hyperactivation in migraine”, Cephalalgia. 2011 June; 31(8): 925-936; Wilkins A J, Wilkinson P. “A tint to reduce eye-strain from fluorescent lighting? Preliminary observations”. Ophthalmology and Physiological Optics. 1991. 11:172-175; Good P A, Taylor R H, Mortimer M J. “The use of tinted glasses in childhood migraine”. Headache. 1991. 31:533-6.

As used herein the term “cold plasma” refers to plasma produced by an apparatus and/or process of the present invention. Plasmas produced by currently available processes are considered “hot” whenever the discharge current exceeds 15 amps. The temperature at 15 amps generally exceeds 160° C. The process and apparatus of the present invention generates cold plasma while operating with a discharge current of 30 amps and a temperature range of between 60° C. and 100° C., preferably 80° C.

As used herein the term “pulse” or “pulsed” refers to a pulsed DC power supply on the plasma generator of an apparatus of the invention by which a full plasma is produced at temperatures below 100° C., at a discharge current of 30 amps. Use of the pulsed DC power supply produces a plasma that is “pulsed” into the vacuum chamber of the deposition apparatus rather than by continuous flow delivery.

As used herein the term “coating” is used to designate a plurality of thin layers deposited onto a substrate, for example, a lens substrate to alter reflection and/or transmittance of light. Coatings are applied to produce thin layer optical filters according to the apparatus and process of the invention.

### Process and Apparatus for Depositing Optical Thin Films

The process and apparatus of the present invention are based on a high-energy, low-temperature plasma ion assisted deposition process (PIAD). An important improvement of the invention over existing plasma-assisted systems as applied to the production of light filters is the use of a pulsed DC assisted source that results in a “cold plasma” process. The deposition apparatus and process creates a dense, highly-energetic electron plasma to ionize and activate gasses such as oxygen, argon, and nitrogen. This process enables the deposition of high quality optical thin films while maintaining substrate temperatures between 60° C. and 100° C., thereby permitting polymeric substrate materials to be coated without changing their optical or mechanical properties.

Construction of optical filters according to the present invention requires a special vacuum evaporation/deposition system that is designed to deposit individual thin film layers of accurately and precisely controlled thickness and refractive index. The assembly of such thin-film layers is known as a multi-layer design, which performs specific optical filtering functions.

The process and apparatus of the invention are compatible with substrate materials that cannot survive the high temperatures of prior deposition processes. Examples of such polymeric substrate materials include, but are not limited to, polycarbonate, allyl diglycol carbonate (e.g. CR-39®), acrylic, urethane based pre-polymer (e.g. TRIVEX®), poly(methyl methacrylate) (PMMA), polyimide film (e.g. KAPTON®), photochromic lenses, and cyclo olefin polymer (COP) (e.g. ZEONEX®), and others used in the ophthalmic and display industries. Existing deposition technologies that use electron-beam evaporation, thermal evaporation, or chemical vapor deposition are not suitable for coating polymeric composition substrate materials having 11-19 layers because they are high-temperature processes, and exceed the maximum temperature tolerated by most polymers, namely 100° C. Presently-available plasma-assisted deposition processes also produce high temperatures and therefore are also unsuitable for deposition of a large number of layers onto polymeric substrates.

The process of the present invention operates at temperatures that are not damaging to polymer eyeglass materials, while enabling the production of durable and adhesive optical coatings.

The new deposition apparatus includes a vacuum vessel that contains deposition sources, evaporation sources, a special plasma-ion assist source, and monitoring devices that are designed to accomplish deposition of the protective coatings for any specific ophthalmic application desired. The vacuum vessel is fabricated from a material having non-magnetic electrical properties so that it neither attracts nor reflects electrons, preferably from solid 304 Stainless Steel.

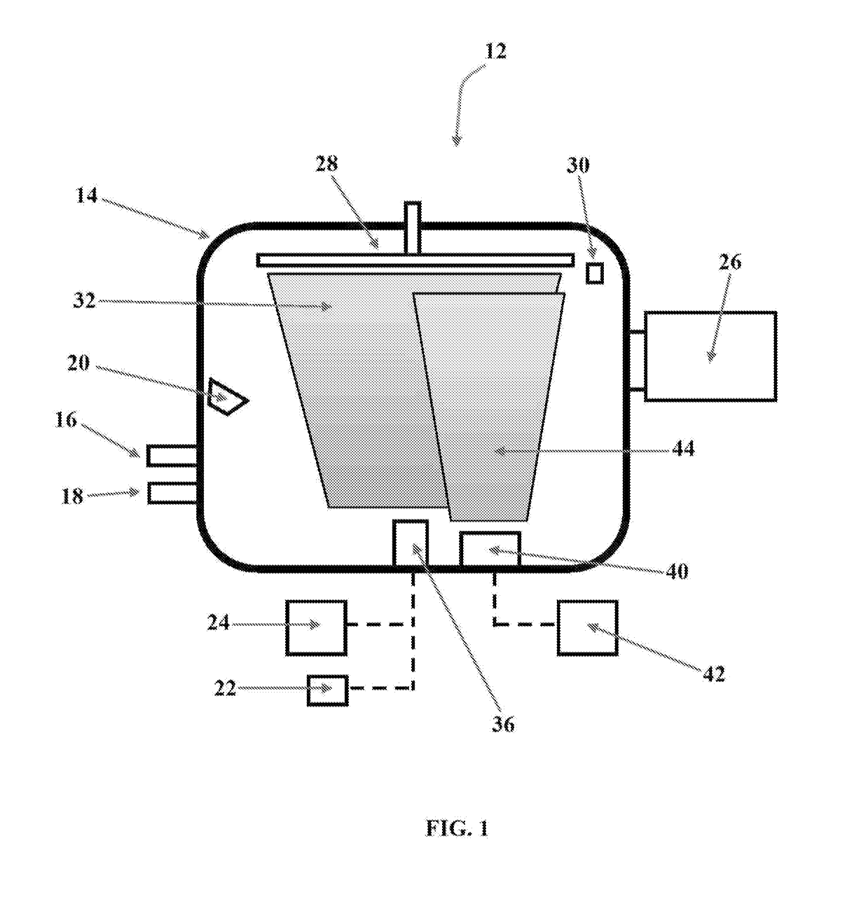

FIG. 1 provides a schematic representation of a cold plasma process thin film deposition apparatus and system of the present invention. The apparatus 12 comprises a vacuum vessel 14, having external components including vacuum pumps 26, pressure monitor 16, gas inlet 18, pulsed DC power supply 22, ion generator power supply 24, and electron beam power supply 42. Vacuum vessel 14 also includes internal components including plasma ion assist source 36, electron beam evaporation source 40, rotating substrate holder 28 for holding the substrate, for example, eye glasses during deposition, thickness monitor 30, and halogen heater 20. FIG. 1 also illustrates schematically ion plasma 32 and vaporized metal species 44 that are produced during operation of the apparatus. The manufacturing process is fully automated and controlled by a computer program.

Substrate holder 28 rotates continuously in order to provide evenly distributed deposited material. The speed of rotation is important for providing the direction and growth of a thin film. At the proper rotation speed, misdirection of the columnar growth in the film is limited, thereby strengthening the film and promoting strong adhesion to the substrate.

The vessel is frequently pumped down during the deposition process to the base operating pressure of 1.0×10⁻⁵ Ton (1.3×10⁻⁸ atmospheric pressure) in order to obtain the best quality thin films. At this range, there is minimal atmospheric gas such as N₂, O₂, H₂O, and CO₂ inside the vacuum vessel that could impair the quality of the film. The pressure inside the vessel is monitored continuously through a convectron gauge for low vacuum and an ionization gauge for high vacuum. It is important to have the proper pressure during deposition to achieve the exact combination of molecules needed to ensure high quality of the film. Excessively high pressure would indicate excessive inert gas inside the vessel that would contaminate the film. Alternatively, inadequate pressure would result in low quality films that are absorbent and not sufficiently transmittant.

Achieving the proper pressure requires a high vacuum pump. The apparatus includes a combination of low vacuum pumps, using a dual stage rotary van pump to reduce the pressure from atmospheric to 5.0×10⁻² Ton, and high vacuum cryogenic pumps to achieve the 1.0×10⁻⁵ Ton operating pressure.

Gas inlet 18 feeds various gas sources into the vacuum vessel during operation. Typically, the preferred high refractive index deposit material, niobium pentoxide (Nb₂O₅), requires additional O₂ gas to be bled into the vacuum vessel to achieve proper deposition. More detail of this aspect is discussed below.

The vacuum vessel includes a set of halogen lamps 20, preferably around 6 kW, which are used to increase the substrate temperature from room temperature (about 27° C.) to about 60° C. until deposition is initiated. Optimal adhesion is achieved by reducing the temperature difference between the deposited materials, running at 70° C., and the substrate.

The electron beam source (EBS) 40 consists of a crucible and a filament assembly. The crucible has between 4 to 8 different pockets for containing the deposition materials, preferably about 25 cc to 40 cc each. The filament assembly consists of a tungsten filament that generates a high energy, concentrated beam of electrons with sufficient power density to provide a melting temperature up to 3,000° C. The electron beam (EB) power supply 42 has 10 kW power that can generate up to 10k Volt and up to 1 Amp filament current.

The EBS is designed with several distinctive features that enhance the evaporation process of deposition material. First, the EBS includes an electro-magnet. Current systems use a permanent magnet to shape the EB. By contrast, the apparatus of the invention provides an EBS that uses a standard permanent magnet and an electro-magnet. The electro-magnet provides very fine tuning in shaping the EB by using a low voltage electronic signal to control the magnet. A second unique feature of the EBS is that it incorporates a backscattering electron trap. During deposition, the electron beam focuses and heats up the deposition materials. While the combined effect of a permanent magnet and electromagnet provide high beam shaping capability, there are some electrons that escape and are scattered. Scattered electrons can sputter unwanted materials that can lead to impurities in the thin film. Industry standard EBSs do not have the means to capture these scattered electrons. The apparatus of the invention incorporates means into the design of the EBS to capture the unwanted scattered electrons.

Another unique aspect of the apparatus of the invention relates to the Plasma Ion Assist Deposition Source (PIADS). Currently available systems generally run at a maximum of 15 amp discharge current to generate the plasma ion cloud. The apparatus of the invention uses a unique PIADS to generate the plasma running up to 30 Amps discharge current. The PIADS of the invention is designed for the production of a cold plasma. Currently available plasma generators that use a conventional power supply and run above 15 Amps discharge current are considered “hot” because they produce temperatures above 160° C. The PIADS of the invention uses a unique power supply configuration that allows it to generate a full plasma at 30 amp discharge current at a temperature between 60° C. and 100° C., preferably 80° C. Most currently available plasma generators use straight alternating current, direct current, or even radio frequency current. The plasma generator of the invention uses a pulse DC power supply. This allows the temperature to remain relatively low since the plasma is pulsed and not continuously bombarded into the vessel. The rate of discharge (loss) of electrons is much lower than the rate of electrons generated, and therefore the plasma remains full. In a preferred embodiment, the power supply provides pulsing frequencies of from 20 kHz to 350 kHz, with a duty cycle up to 45%.

Another important advantage of the apparatus design and implementation is the absence of arcing during the deposition process that would, if present, create defects in the coating. The metal species components of the chemical compounds that compose the evaporated and deposited coating materials are completely oxidized by the reactive plasma ions. The result is that the thin film layers are grown without absorption and with high packing density, and therefore the coatings on a polymeric substrate such as eyewear are stable to ambient environmental conditions.

### Process

In another aspect, the invention relates to a coating deposition process for manufacturing optical filters comprising thin film layers on a substrate, preferably a polymeric substrate. The process of the invention provides a high-energy plasma created with electrons by ionizing an appropriate gas such as argon, nitrogen, or oxygen, preferably argon, and by oxidizing oxygen gas. The process results in high refractive index and low refractive index transparent oxide films layered onto a substrate. Appropriate metal oxides include those derived from one or more of niobium, titanium, tantalum, aluminum, silicon, yttrium, hafnium, scandium, lanthanum, chromium. Low refractive index metal oxides include silicon dioxide, aluminum oxide, or any other evaporable, transparent, and physically stable low-index compound. Preferably, low refractive index metal oxides exhibit a visible range refractive index of from about 1.4 to about 1.6; alternatively from 1.4 to 1.6, and an extinction coefficient value of less than 0.005, preferably less than 0.001. High refractive index metal oxides include niobium oxide, tantalum oxide, titanium oxide, hafnium oxide, yttrium oxide, or any other evaporable, transparent, and physically stable high-index compound. Preferably, high refractive index metal oxides exhibit a visible range refractive index of from about 1.9 to about 2.4; alternatively from 1.9 to 2.4, and an extinction coefficient value of less than 0.005, preferably less than 0.001.

The high energy plasma creates an environment in which the vaporized metal and metal sub-oxide species are completely oxidized and a thin solid film of each metal oxide compound condenses and grows on the substrate.

To illustrate the process of the invention more fully, preparation of an optical filter comprising high refractive index niobium oxide and low refractive index silicon oxide is described hereinbelow. Design and optimization of any particular filter depends on the objectives and intended use for the filter, i.e. the desired transmittance and reflectance properties, the coating materials that will be used for fabricating the filter, the composition of substrate, etc. A number of thin film design software tools are available for designing and optimizing the specific parameters of an optical filter such as, for example, the number of layers, the thickness of layers, reflectance, transmittance, absorbance, optical density, loss, color, luminance, etc. A commercially available software package for this purpose is TFCalc™ (Software Spectra, Inc. Portland, Oreg.).

Individual layers of niobium oxide (high refractive index) and silicon oxide (low refractive index) are laid onto a suitable polymeric substrate by evaporating preparations of niobium oxide and silicon oxide with electron-beam heating. Preferably, the top layer of the filter is the low refractive index material, i.e. silicon oxide though it could also be the high refractive index niobium oxide. The physical thickness of the growing film layers is monitored by an automated process that is a component part of the deposition apparatus, in accord with the design parameters for each layer, each layer being terminated at a preprogrammed thickness. The process involves use of a pulsed DC plasma assist which operates at frequencies between 100 kHz and 200 kHz which results in the primary plasma discharge operating at lower power than a hot plasma process. A high density of reactive gas and metal species is produced at the substrate and the coating deposition process produces ion energy near 100 eV.

The deposition process of the invention produces multi-layer coatings that are stable to humid/arid environmental variations. Since the process operates within a temperature range of 60° C. to 100° C., high quality optical films can be produced using temperature-sensitive substrates such as polymers including, but not limited to, polycarbonate, allyl diglycol carbonate (e.g. CR-39®), acrylic, urethane based pre-polymer (e.g. TRIVEX®), and other polymeric materials commonly used for eyewear or optical instruments.

The process of the invention can be widely applied to coat, for example, eyeglass lenses, computer displays, instrument displays and panels, heads-up helmets and avionics displays.

In one embodiment, the process of the invention is applied to produce multi-layer thin film coatings to create optical filters, for example, to provide a specific narrow rejection band centered at a desired wavelength, for example, at 480 nm or at 620 nm. The rejection of incoming light is preferably 65% to 85%, with 75% being most preferred. For therapeutic applications of optical filters of the invention, variations of light attenuation from 65% to 85% can be beneficial to certain patient populations, for example, those suffering from a photophobic condition.

The process of the invention produces thin film depositions having from 11 to 19 layers depending on the reflection percentage desired. Three main criteria are considered for the coating: (i) that it meet the reflection specification within ±2%, (ii) that it keep the full width half max (FWHM) less than 60 nm centered around the desired wavelength within ±3 nm and (iii) that it pass all mechanical durability testing requirements set by ophthalmic industry.

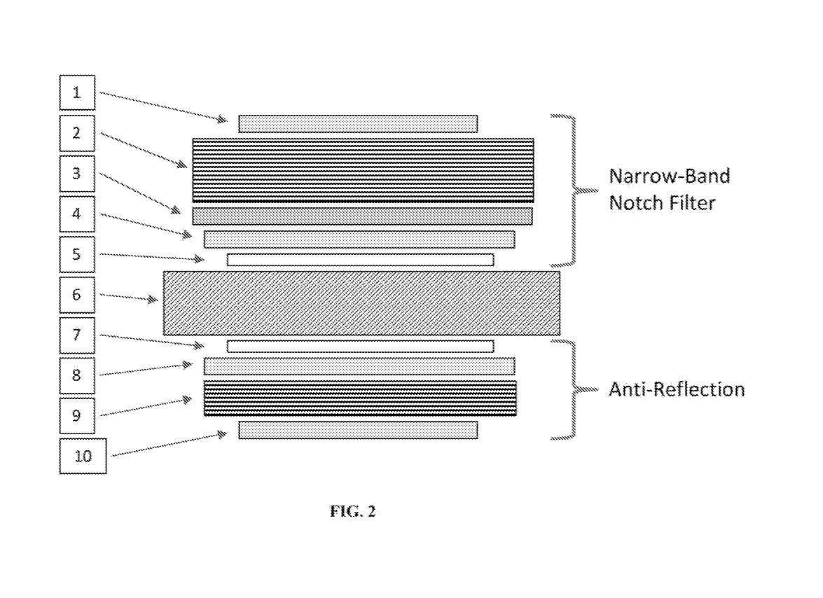

In a preferred embodiment, the process of the invention uses niobium pentoxide (Nb₂O₅) as the high index of refraction material, and silicon dioxide (SiO₂) as the low index of refraction material. These two materials make up the bulk of the rejection optical filter (i.e. notch filter), as well as the anti-reflection portions of an optical lens produced by the process. Other coating materials may also be included as additional layers, for example, adhesion layers 5 and 7, index matching layers 4 and 8, and hydro/oleophobic layers 1 and 10 (see FIG. 2).

The process of the invention begins by loading materials into the appropriate pockets of the Electron Beam Source (EBS), and loading the substrate onto the rotation fixture. Vacuum pumps reduce the system from atmospheric pressure to the base operating pressure of 1.0×10⁻⁵ Torr. A heater within the vacuum chamber keeps the substrates at an acceptable temperature of about 60° C. During deposition, rotation of the substrate fixture promotes even distribution of coating materials from the center to the outside of the fixture

When the desired operating pressure is reached, a pre-clean process is initiated. High energy cold plasma is injected into the system to bombard the substrate surface and remove all unwanted particles such as dust and lint. The pre-clean step performs an additional function which is to charge the substrate surface to promote subsequent coating with the deposition materials. The coating materials adhere better when the substrate surface is charged. The discharge current is set at 30 Amps and a mixture of 50/50 argon and oxygen gases is provided to generate the plasma and provide the medium to carry ions and electrons.

Deposition begins after completion of the pre-clean step. Referring to FIG. 2 (which is explained further hereinbelow), the concave side of the substrate lens (back/anti-reflection surface) is coated first, i.e. layers 7 to 10. Layers 1 and 10 are exterior hydro/oleophobic layers. Layer 3 is a partial absorbing layer. Layers 4 and 8 are index matching layers. Layers 5 and 7 are adhesion promoting layers. Layer 6 is the lens substrate. Layer 2 is the narrow band multi-layer reflection stack, and layer 9 is an anti-reflection multi-layer stack. Control of the deposition of layers 1, 3, 4, 5, 7, 8, and 10 is not as crucial as control of layers 2 and 9, particularly with regard to the notch filter stack (layer 2). Each layer of coating material is evaporated and deposited onto the substrate one at a time. By alternating the high and low index material, an optical interference filter is formed, for example, the anti-reflection (AR) coating (layers 7-10). Upon completion of AR, the system is vented, substrate removed, and the substrate is flipped over so that the front, or convex side of the substrate can be coated.

The narrow band notch filter, layers 1 to 5 is created by repeating the coating sequence. There are 3 important factors in creating a successful notch filter: (i) control of the index of refraction by using the correct ratio of gas bleeding into the system, (ii) control of the thickness of the films, and (iii) control of the plasma potential energy level in the system.

High index of refraction materials such as Nb₂O₅ require a proper amount of oxygen in the system during deposition. In solid form, Nb₂O₅ has five oxygen atoms associated with it. During deposition, a large current of electrons, up to 400 mA, generates temperatures up to 1,500° C. which evaporates Nb₂O₅. At this elevated temperature and reduced pressure (1.0×10⁻⁵ Ton), some of the oxygen atoms are disassociated from Nb₂O₅ giving rise to Nb₂O₃. Nb₂O₃ is not an optical grade material for coating, even for infinitely small amounts. In order to address this problem, a continuous flow of 5 sccm/min (standard cubic centimeter per minute) of O₂ is added into the system via the gas inlet. By doing so Nb₂O₅ can be regenerated. It is important to control how much oxygen is introduced into the system. Excessive oxygen will change the composure of the material causing lower index of refraction while too little oxygen causes higher index of refraction leading to more absorption.

To form a 15 layer coating on a substrate, precise index control is crucially important since an error in each layer can accumulate up to a 15-fold error. According to Snell's Law, reflection is described as:

R={[n−1]/[n+1]}²
Where R=Reflection per surface layer
n=index of refraction of coated material (n=2.34 for Nb₂O₅)
   A 1.0% change in the index for Nb₂O₅ can lead to a change of 0.30% reflection in one single layer. In 15 layers, the accumulated reflection error can be up to 4.5%. The tolerance requirement for a device of the invention is ±2%. Therefore, it is crucially important to achieve the correct index of material.

Thickness of the layers also plays an important role in dictating the reflection that is achieved, and it is as important to control as the index of refraction. The thickness for each layer, regardless of material, can be as little as 10 Angstrom to a few thousand Angstrom (1 Angstrom equals to 1.0×10⁻¹⁰ m; 0.000000004 inch). The radius of an average atom is 1.5 Angstrom. Therefore, extremely precise instrumentation is required to measure the total thickness of the film. For this purpose, a crystal quartz monitor is used to measure the thickness of the film. The quartz crystal resonator measures the mass of the atom as it is deposited onto the crystal. As more mass is deposited, the resonator reads the frequency change and calculates the thickness of the film. The resonator is capable of measuring frequency in the range of 5 MHz. At this frequency, even the lightest atom can be measured.

In its simplest form, a target wavelength (λ), for example 480 nm, can be calculated using the equation:

λ(480 nm)=4nd
where 480 nm is the target wavelength
n=index of refraction of coated material
d=thickness of the film
   A 1.0% change in thickness control can lead to a 1.0% change in the target wavelength, in this case from 480 nm to a range of 475 nm to 485 nm, and out of the desired spectral specification range of ±3 nm.

The most important control of the process relates to the plasma energy level. An apparatus and process of the invention rely on use of a pulse DC Plasma Ion Assist Deposition Source (PIADS). The process generates a cold plasma, while running at 30 Amps discharge current, which is more than double that of a conventional ion plasma generator. Despite the high discharge current, the process maintains a temperature well below the melting point of polymeric materials.

While optical multilayer coating and ion assisted deposition are known, they are limited to applying 10 or fewer thin films onto a polymer substrate. For instance, anti-reflection coating for eyewear typically provide 5-7 layers having a total thickness of 230 nm. At such minute thicknesses, the mechanical stresses between a thin film, solid metal base material, and polymer substrate does not exhibit disruptive mechanical stress conditions. However, the notch filter coatings of the present invention can result in total thicknesses as high as 3,800 nm or 3.8 μm. At this substantially higher thickness, mechanical stress between the film and polymer substrate becomes an issue causing film failure such as crazing (a form of fine line cracking in the film), peeling (film lifts off the substrate), or de-lamination (micro-fracturing in the film resulting in haziness).

The process of the present invention enables the application of 3,800 nm thick thin-films on a polymer substrate, without leading to the aforementioned mechanical stress problems. The process produces a very high energy, 30 Amp discharge current, to generate the ion plasma while maintaining a temperature within a range of 60° C. to 100° C., preferably at 80° C. These two features are key in successfully depositing thick films onto a polymeric substrate. High energy plasma produces an abundance of ions in the system. The high energy ions bombard the substrate surface and pack the coating molecules tightly onto the substrate and into each other to create a highly dense and tightly packed film to form a continuous bond between polymer and solid. Although mechanical stress between solid and polymer remains, it does not damage the film, and thick films can be produced by the process of the invention without exhibiting crazing, hazing, or peeling.

### Product

Another aspect of the present invention relates to optical filter products including those produced by the process of the invention, for example, eyewear and light sources. Products such as eyewear for attenuating certain wavelengths of light are desirable for treating photophobic effects and related neurological responses, and for rejecting ultraviolet and near-infrared wavelengths.

The design, fabrication, and production of optical filters that remove or attenuate wavelengths or wavelength bands that are responsible for photophobic responses requires a critical arrangement of thin layers. The function and design of such filters is to reflect narrow-bandwidth wavelengths from the visible spectrum. Selective wavelength attenuation is achieved by the interference of light waves, and not by absorption, as is the case with prior art filters. Prior optical filters used tinted plastics that absorb a greater fraction of blue light than green and red light. As such, the overall transmission of visual light was reduced, and color perception distorted by eyewear of this type.

The process and apparatus herein described produces filters that reject specific narrow portions of the visual spectrum by reflection to provide protection against or reduction of photophobic reactions. A further advantage is the ability to, by design, reject wavelengths in the red part of the visible spectrum that, along with blue wavelengths, are known to be responsible for debilitating photophobic and related light-stimulated neurological responses.

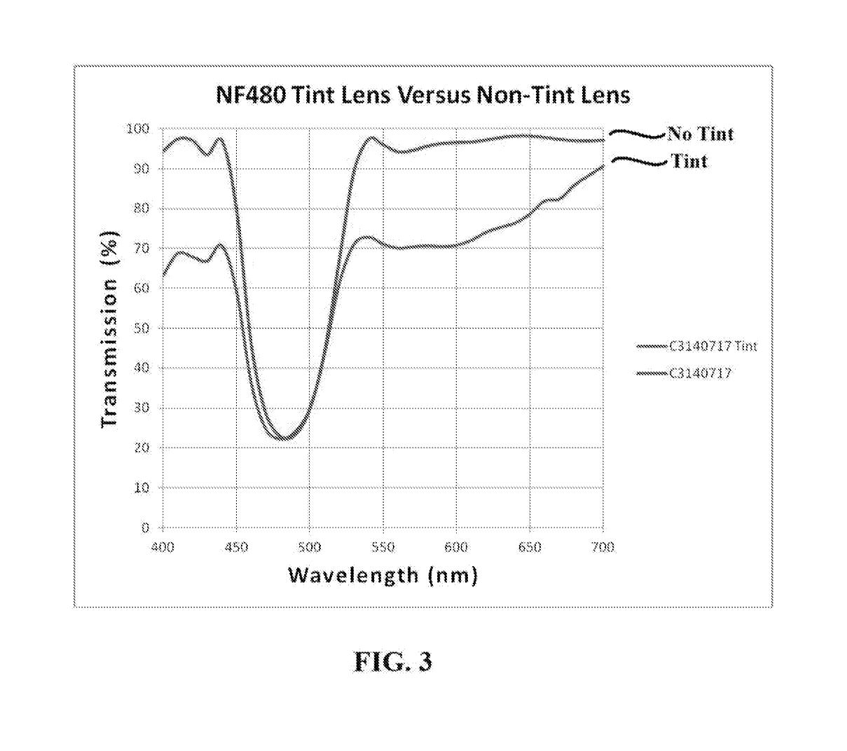

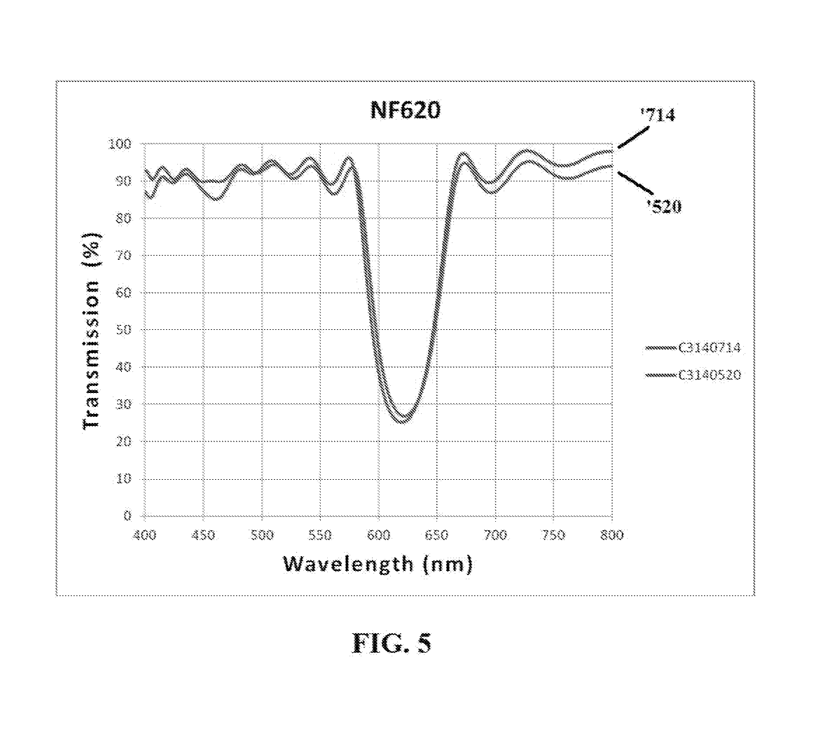

FIG. 2 illustrates the general construction of multi-layer coatings on a lens polymeric substrate produced by the apparatus and process of the invention. The upper system of layers 1 thru 5, comprise the spectral reflecting filter (notch filter) whose spectral transmission and reflection are illustrated in FIGS. 3 and 5. Layer 3 provides a measured amount of absorption that reduces back reflection of ambient light. Layer 6 is the substrate. Layers 7 thru 10 comprise the anti-reflection coating deposited on the rear or exiting face of the optic. Layers 5 and 7 are adhesion-promoting layers necessary for bonding the multi-layer coatings to various polymeric substrate compositions. Layers 4 and 8 are optical impedance matching layers that function to maximize light transmission of the desired wavelengths and color rendition.

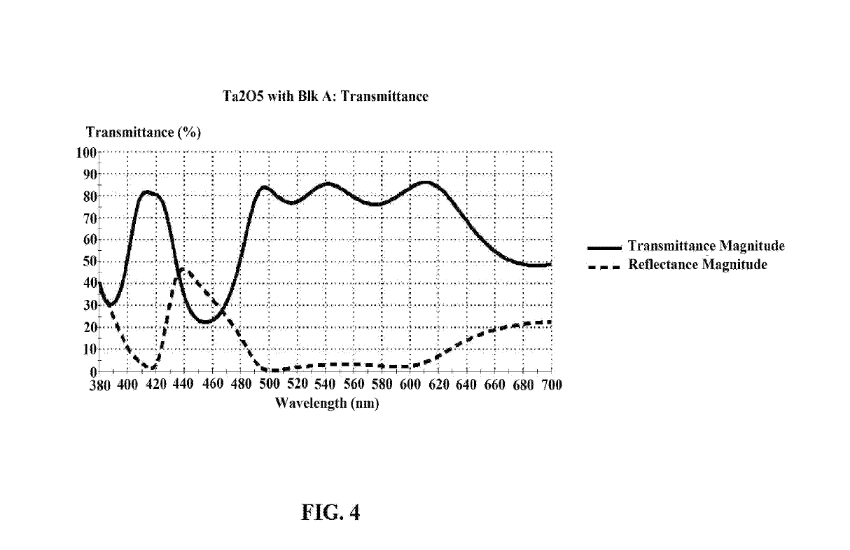

FIGS. 3 and 4 depict the spectral transmission and reflection of the coating produced by the thin-film design of FIG. 2. FIG. 3 shows the transmittance of a typical protective design deposited on eyeglass lenses. This design rejects a substantial amount of blue light centered in a narrow band at wavelengths 470 to 490 nm while providing sufficient luminous transmission so as not to reduce vision (see profile C3140717). The profile identified as “C3140717 Tint” depicts a variation in which the coating was deposited on tinted glasses. Coating tinted lenses with the narrow band reflecting multi-layer series reduces unwanted background reflections and glare.

FIG. 4 shows the transmittance and reflectance of another design variation to reduce specific reflection. This design includes an absorbing layer, and thereby does not require tinted lenses. The reflection is less than half of the reflection of the coating depicted in FIG. 3 with lower loss of luminous transmission. This design variation also reduces UV and long-wave red light.

Another design variation (FIG. 5) of the present invention incorporates a filter that reduces a band of red light centered near 620 nm, but otherwise provides similar behavior and protection to the filter for 480 nm described above. The 620 nm band of wavelengths is also known to stimulate photophobic and related neurological responses in some individuals. FIG. 5 shows the spectral transmittance of a 620 nm filter that can be produced by the same filter deposition apparatus as that used for the 480 nm filter (FIG. 3).

Other design variations for protective filters of the invention are possible including combining the rejection bandpasses into one thin-film coating design that is deposited onto eyewear.

In one embodiment, the invention relates to optical filters applied to eyewear having polymeric lenses for the prevention and reduction of photophobic effects and responses. Coatings are applied to lenses to selectively attenuate wavelengths in the visible spectrum that are stimuli of photophobic reactions such as migraine headache or benign essential blepharospasm. The multi-layer thin film optical filter is fabricated to reflect at least 75% of visible light in a narrow band at 480 nm or 620 nm. A filter for this purpose comprises a narrow-band spectral reflecting filter on the light-entering side of a polymeric lens substrate, a partially absorbing layer, an optical impedance matching layer to maximize light transmission of the desired wavelength and color rendition and an adhesion promoting layer. On the exiting side of the lens substrate, the filter includes a multi-layer anti-reflection coating comprising an adhesion promoting layer, an optical impedance matching layer to maximize light transmission of the desired wavelength and color rendition, and a multi-layer anti-reflecting coating. The thin film layers comprise alternating high-index and low-index thin film layers to create an interference filter designed to reflect the desired narrow spectral bands of wavelengths, and transmit the remaining light to the wearer's eyes.

Another aspect of the invention relates to optical filters produced by a process of the present invention for any purpose including, for example, use on eyewear for the prevention and reduction of photophobic effects and responses. In this aspect, optical filters are produced by the vacuum evaporation/deposition system of the present invention that is designed to deposit individual thin film layers of accurately and precisely controlled thickness and refractive index with substrate materials that cannot survive the high temperatures of prior art deposition methods which rely on electron-beam evaporation, thermal evaporation, chemical vapor deposition, or plasma-assisted deposition which are high-temperature processes that exceed the maximum temperature tolerated by most polymers, namely 100° C.

Optical filters produced by the process of the present invention have thin film layers with high, bulk-like packing density that provides high environmental and mechanical durability, high adherence strength on polymer compositions, and low intrinsic stress.

Optical coatings of the invention are designed to reflect one or more narrow wavelength intervals of the visible spectrum. In one embodiment, the wavelength interval centers on melanopsin absorption bands at 480 nm or 620 nm, while transmitting the remainder of the visible spectrum with high efficiency. Preferably, the optical coating further includes components to reject ambient or background light and provide high contrast between photopic transmission and transmission in the melanopsin spectral band. A filter of the present invention performs in daylight or low-light conditions to effectively protect against and reduce the severity of photophobic reactions.

Optical filters according to this aspect of the invention comprise a plurality of alternating layers designed and assembled to produce one or more narrow reflecting spectral bands of specific pre-determined depths. Preferably, the plurality of alternating layers is designed and assembled to produce one or more narrow spectral reflection bands whose reflectance is between 90% and 25% and a residual integrated transmission in the range of about 75% to 90% for the photopic wavelengths. Optical filters according to this aspect of the invention have a plurality of alternating layers designed and assembled to produce a reflecting band or bands whose center wavelength is a predetermined specific value; alternatively whose bandwidth is a predetermined specific value. In one embodiment, one or more mildly absorbing layers are inserted for the purpose of eliminating ambient and retro reflections. Desirably, a hydro-phobic layer is applied to the exposed outer surface(s) of the coating stack to provide water drop immunity and reduced sensitivity to oily smudging. An optical filter may further include impedance-matching layers to maximize light transmission.

### Methods to Treat Photophobic Conditions

The present invention further relates to a method for treating or ameliorating the effects of a photophobic condition such as migraine headache, blepharospasm, or other light-stimulated neurological reactions. Some photophobic patients respond adversely to light at or near 480 nm, while others experience adverse responses to light at or near 620 nm.

According to this aspect of the invention a patient is diagnosed with a photophobic or other light-sensitive condition, including determining sensitivity to light at 480 nm or 620 nm. The condition is treated by providing eyewear having an optical filter of the present invention applied to a polymeric lens substrate, designed to interfere with light at either 480 nm or 620 nm. The function of such optical eyewear devices is to modify the spectral content of light sensed by the eye, specifically to attenuate or eliminate those wavelengths or bands of wavelengths of visual light that are associated with a high occurrence frequency of photophobic reactions. A narrow spectral bandwidth filter of the invention applied to eyeglasses and other optical surfaces function to reduce the severity of photophobic and other vision-related neurological reactions.

Optical filters of the invention can also be applied to regulate circadian rhythms and treat other light-sensitive conditions including head/brain trauma, and drug-related eye problems.

While the form of the method and system herein described constitutes one or more preferred embodiment(s) of the invention, it should be understood that the invention is not limited to the precise form of apparatus or device, and that changes may be made therein without departing from the scope of the invention.

1. A thin-film deposition apparatus comprising
a) a vacuum chamber;
b) a gas inlet;
c) a vacuum pump;
d) an electron beam source having a permanent magnet and an electro-magnet for shaping an electron beam; and
e) a plasma ion assist deposition source to produce a cold plasma, wherein said deposition source is operably connected to a pulsed DC power supply.

2. A thin-film deposition apparatus as in claim 1 wherein said electron beam source further comprises means for capturing backscattered electrons.

3. A thin-film deposition apparatus as in claim 1 wherein said plasma ion assist deposition source produces a discharge current of 30 Amps while maintaining a temperature between 60° C. to 100° C.

4. A thin-film deposition apparatus as in claim 3 wherein said DC power supply provides a pulsing frequency of from 20 kHz to 350 kHz and a duty cycle up to 45%.

5. A thin film deposition apparatus as in claim 4 further comprising a heater, rotating substrate fixture, film thickness monitor, and pressure monitor.

6. A thin-film deposition apparatus comprising
a) a vacuum chamber including a heater, rotating fixture, and film thickness monitor;
b) gas inlet;
c) vacuum pumps;
d) pressure monitor;
e) electron beam source having a crucible and filament assembly operably connected with an electron beam power supply; and
f) plasma ion assist deposition source to produce a cold plasma at 30 amp discharge current and a temperature below 100° C.;
wherein said electron beam source further comprises a permanent magnet and an electro-magnet for shaping the electron beam and wherein said plasma ion assist deposition source is connected to a pulsed DC power supply such that plasma is pulsed into the vacuum vessel.

7. A thin-film deposition apparatus as in claim 6 wherein said DC power supply produces a pulsing frequency of from 20 kHz to 350 kHz with a duty cycle up to 45%.

8. A cold plasma ion assisted deposition process to produce an optical coating on a temperature sensitive substrate for selectively attenuating wavelengths of light in the visible spectrum, comprising the steps of:
a) providing a temperature sensitive substrate to a thin film deposition apparatus having a vacuum chamber;
b) reducing the pressure inside the vacuum chamber to 1×10⁻⁵ Torr;
c) producing a high energy cold plasma by ionizing a gas with a plasma ion assist deposition source (PIAD) said source connected to a pulsed DC power supply at a discharge current of 30 Amps;
d) pre-cleaning a surface of the substrate with the high energy cold plasma to remove particles and charge the surface;
e) vaporizing high refraction index and low refraction index deposition metal species with an electron beam source said source having a permanent magnet and an electro-magnet for shaping the electron beam; and
f) depositing thin layers of high refractive index metal oxide material and low refractive index metal oxide material in alternating order onto the substrate to produce the optical coating.

9. A process as in claim 8, wherein the high-energy plasma is created with electrons and the gas comprises oxygen as an oxidizing gas and argon as a working gas.

10. A process as in claim 9 wherein said PIAD provides complete oxidation of metal oxide film layers at a substrate temperature between 60° C. to 100° C.

11. A process as in claim 10 wherein transparent metal oxide compound films are deposited which contain a metal selected from the group consisting of niobium, titanium, tantalum, aluminum, silicon, yttrium, hafnium, scandium, lanthanum, and chromium.

12. A process as in claim 11 wherein the substrate is a polymeric material and the coating comprises a thin-layer films rejection portion and a thin-layer films anti-reflection portion.

13. A process as in claim 12 wherein the coating attenuates wavelengths that are stimuli of photophobic reactions selected from 480 nm and 620 nm.

14. A process as in claim 13 wherein said rejection portion has from 11-19 layers and said anti-reflection portion has from 5-7 layers.

15-30. (canceled)

31. An optical filter on a polymeric substrate comprising a thin layer narrow band notch filter coating having 11-19 layers and a thin layer anti-reflection coating having 5-7 layers of alternating high refractive index and low refractive index transparent material wherein the thin film layers have high packing density and high environmental and mechanical durability.

32-38. (canceled)

39. An optical filter as in claim 31, wherein the optical filter is designed to reflect a narrow wavelength interval of the visible spectrum that is spectrally centered on melanopsin absorption bands.

40. An optical filter as in claim 39 wherein the melanopsin absorption bands are 480 nm and 620 nm.

41-44. (canceled)

45. An optical filter as in claim 31, wherein the optical filter comprises a multi-layer structure of alternating high-refractive index and low-refractive index transparent materials.

46. (canceled)

47. An optical filter as in claim 31, wherein the optical filter includes optical interference filters composed of metal oxide compounds.

48-49. (canceled)

50. An optical filter as in claim 47, wherein the optical interference filters are composed of metal oxide layers exhibiting a visible-range refractive index in a range of 1.4 to 1.6 and extinction coefficient value less than 0.005.

51-67. (canceled)
